(19) United States
(12) Patent Application Publication
(10) Pub. No.: US 2026/0215114 A1
(43) Pub. Date: Jul. 23, 2026

(54) DISPLAY APPARATUS AND ELECTRONIC APPARATUS INCLUDING THE SAME

(71) Applicant: Samsung Display Co., Ltd., Yongin-Si (KR)

(72) Inventors: Nahyeon Cha, Yongin-si (KR); Junhyun Park, Yongin-si (KR); Hwarang Lee, Yongin-si (KR); Junki Jeong, Yongin-si (KR)

(21) Appl. No.: 19/454,812

(22) Filed: Jan. 21, 2026

(30) Foreign Application Priority Data
Jan. 22, 2025 (KR) 10-2025-0009814

(51) Int. Cl. H10K 59/131; G09G 3/3233; H10K 59/121

(52) U.S. Cl. CPC H10K 59/131; H10K 59/1213; H10K 59/1216; G09G 3/3233; G09G 2300/0426; G09G 2300/0819; G09G 2300/0852; G09G 2300/0861

(57) ABSTRACT

A display apparatus includes a substrate, a 1-1 gate line and a 1-2 gate line, extending in a first direction on the substrate and being spaced apart from each other, a data line extending in a second direction intersecting the first direction, and a first pixel circuit and a second pixel circuit arranged in the first direction, with the data line therebetween, wherein the first pixel circuit is connected to the 1-1 gate line and the second pixel circuit is connected to the 1-2 gate line, each of the first pixel circuit and the second pixel circuit including a storage capacitor, and a holding capacitor including a first holding electrode connected to a first storage electrode of the storage capacitor, and wherein a capacitance of the storage capacitor of the first pixel circuit is different from a capacitance of the storage capacitor of the second pixel circuit.

### CROSS-REFERENCE TO RELATED APPLICATION

This application is based on and claims priority under 35 U.S.C. § 119 to Korean Patent Application No. 10-2025-0009814, filed on Jan. 22, 2025, in the Korean Intellectual Property Office, the disclosure of which is incorporated by reference herein in its entirety.

### BACKGROUND

### 1. Field

One or more embodiments relate to a display apparatus and an electronic device including the same.

### 2. Description of the Related Art

Recently, applications of display apparatuses have diversified. In addition, display apparatuses have become thinner and lighter, and thus the range of use of display apparatuses is expanding.

A display apparatus includes a display panel, and the display panel includes a display element which implements a pixel and a pixel circuit for controlling an electrical signal applied to the display element. The pixel circuit includes a thin-film transistor (TFT), a capacitor, and a plurality of wirings.

Applications of display apparatuses have diversified and various designs for improving the quality of display apparatuses have been attempted.

### SUMMARY

One or more embodiments include a highly reliable display apparatus and an electronic device including the same. However, the one or more embodiments are only examples, and the scope of the disclosure is not limited thereby.

Additional aspects will be set forth in part in the description which follows and, in part, will be apparent from the description, or may be learned by practice of the presented embodiments of the disclosure.

According to one or more embodiments, a display apparatus includes a substrate, a 1-1 gate line and a 1-2 gate line extending in a first direction on the substrate and being spaced apart from each other, a data line extending in a second direction intersecting the first direction, and a first pixel circuit and a second pixel circuit arranged in the first direction with the data line therebetween, wherein the first pixel circuit is connected to the 1-1 gate line and the second pixel circuit is connected to the 1-2 gate line, each of the first pixel circuit and the second pixel circuit including a first transistor including a first semiconductor layer and a first gate electrode, a storage capacitor including a second storage electrode connected to the first gate electrode, and a holding capacitor including a first holding electrode connected to a first storage electrode of the storage capacitor, wherein a capacitance of the storage capacitor of the first pixel circuit is different from a capacitance of the storage capacitor of the second pixel circuit.

In an embodiment, the first pixel circuit and the second pixel circuit may share the data line.

In an embodiment, the display apparatus may further include a first light-emitting diode connected to the first pixel circuit and a second light-emitting diode connected to the second pixel circuit, and the first light-emitting diode and the second light-emitting diode may emit light of a same color.

In an embodiment, the storage capacitor may further include a third storage electrode arranged above the second storage electrode, wherein the third storage electrode may be connected to the first storage electrode via a contact hole.

In an embodiment, an area of the first storage electrode of the first pixel circuit may be equal to an area of the first storage electrode of the second pixel circuit, and an area of the third storage electrode of the first pixel circuit may be equal to an area of the third storage electrode of the second pixel circuit.

In an embodiment, a width of the second storage electrode of the first pixel circuit in the first direction may be different from a width of the second storage electrode of the second pixel circuit in the first direction.

In an embodiment, an edge of the second storage electrode may be arranged on an inner side of an edge of the first storage electrode in a plan view.

In an embodiment, a capacitance of the holding capacitor of the first pixel circuit may be different from a capacitance of the holding capacitor of the second pixel circuit.

In an embodiment, the holding capacitor may further include a second holding electrode arranged in a same layer as the first semiconductor layer, wherein a width of the second holding electrode of the first pixel circuit in the first direction may be different from a width of the second holding electrode of the second pixel circuit in the first direction.

In an embodiment, the holding capacitor may further include a second holding electrode arranged in a same layer as the first semiconductor layer, a third holding electrode arranged above the first gate electrode, and a fourth holding electrode arranged above the third holding electrode, wherein the fourth holding electrode may be provided as part of a driving voltage line extending in the second direction.

In an embodiment, the fourth holding electrode may include a first branch and a second branch in an area overlapping the third holding electrode, wherein the first branch arranged in the first pixel circuit may be continuous, and the first branch arranged in the second pixel circuit may be discontinuous and include a gap.

In an embodiment, the fourth holding electrode may include a first branch and a second branch in an area overlapping the third holding electrode, wherein at least one width of the first branch and the second branch arranged in the first pixel circuit may be different from a width of each of the first branch and the second branch arranged in the second pixel circuit.

In an embodiment, the display apparatus may further include a third pixel circuit and a fourth pixel circuit arranged in a next row with respect to the first pixel circuit and the second pixel circuit and arranged with the data line therebetween, wherein a capacitance of a storage capacitor included in the third pixel circuit may be different from a capacitance of the storage capacitor included in the first pixel circuit.

In an embodiment, the display apparatus may further include a first light-emitting diode connected to the first pixel circuit, a second light-emitting diode connected to the second pixel circuit, a third light-emitting diode connected to the third pixel circuit, and a fourth light-emitting diode connected to the fourth pixel circuit, wherein the first light-emitting diode, the second light-emitting diode, the third light-emitting diode, and the fourth light-emitting diode may emit light of a same color.

According to one or more embodiments, a display apparatus includes a substrate, a 1-1 gate line and a 1-2 gate line, extending in a first direction on the substrate and being spaced apart from each other, a data line extending in a second direction intersecting the first direction, and a first pixel circuit and a second pixel circuit, which share the data line and are arranged in the first direction, wherein the first pixel circuit is connected to the 1-1 gate line and the second pixel circuit is connected to the 1-2 gate line, each of the first pixel circuit and the second pixel circuit includes a first transistor including a first semiconductor layer and a first gate electrode, a storage capacitor including a second storage electrode connected to the first gate electrode, and a holding capacitor including a first holding electrode connected to a first storage electrode of the storage capacitor, wherein a capacitance of the holding capacitor of the first pixel circuit is different from a capacitance of the holding capacitor of the second pixel circuit.

In an embodiment, the holding capacitor may further include a second holding electrode arranged in a same layer as the first semiconductor layer, wherein a width of the second holding electrode of the first pixel circuit in the first direction may be different from a width of the second holding electrode of the second pixel circuit in the first direction.

In an embodiment, the holding capacitor may further include a second holding electrode arranged in a same layer as the first semiconductor layer, a third holding electrode arranged above the first gate electrode, and a fourth holding electrode arranged above the third holding electrode, wherein the fourth holding electrode may be provided as part of a driving voltage line extending in the second direction.

In an embodiment, an area of the fourth holding electrode of the first pixel circuit may be different from an area of the fourth holding electrode of the second pixel circuit.

According to one or more embodiments, an electronic apparatus includes a display apparatus, wherein the display apparatus includes a substrate, a 1-1 gate line and a 1-2 gate line, extending in a first direction on the substrate and being spaced apart from each other, a data line extending in a second direction intersecting the first direction, and a first pixel circuit and a second pixel circuit arranged in the first direction with the data line therebetween, wherein the first pixel circuit is connected to the 1-1 gate line and the second pixel circuit is connected to the 1-2 gate line, each of the first pixel circuit and the second pixel circuit including a first transistor including a first semiconductor layer and a first gate electrode, a storage capacitor including a second storage electrode connected to the first gate electrode, and a holding capacitor including a first holding electrode connected to a first storage electrode of the storage capacitor, wherein a capacitance of the storage capacitor of the first pixel circuit is different from a capacitance of the storage capacitor of the second pixel circuit, or a capacitance of the holding capacitor of the first pixel circuit is different from a capacitance of the holding capacitor of the second pixel circuit.

In an embodiment, the electronic apparatus may be one of a smartphone, a tablet PC, a laptop, a TV, a desk monitor, smart glasses, a head-mounted display, a smart watch, an instrument panel of a vehicle, a center fascia, a center information display (CID), and a room mirror display.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a plan view schematically illustrating a display apparatus according to an embodiment;

FIG. 2 is an equivalent circuit diagram schematically illustrating a light-emitting diode, which is a light-emitting element corresponding to any one pixel of a display apparatus according to an embodiment, and a pixel circuit electrically connected to the light-emitting diode;

FIG. 3 is a cross-sectional view schematically illustrating a portion of a display apparatus according to an embodiment;

FIG. 4 is a planar layout diagram schematically illustrating a pixel circuit and some of wirings arranged in a display area of a display apparatus;

FIG. 5 is a layout diagram schematically illustrating positions of transistors, a storage capacitor, and a holding capacitor in pixel circuits included in a display apparatus according to an embodiment;

FIGS. 6, 7, 8, 9 and 10 are layout diagrams schematically illustrating components, such as the transistors, the storage capacitor, and the holding capacitor of the display apparatus shown in FIG. 5, layer by layer;

FIG. 11 is a plan view illustrating a partial configuration of a display apparatus according to an embodiment;

FIG. 12 is a plan view illustrating a partial configuration of a display apparatus according to an embodiment;

FIG. 13 is a plan view illustrating a partial configuration of a display apparatus according to an embodiment;

FIG. 14 is a plan view illustrating a partial configuration of a display apparatus according to an embodiment;

FIG. 15 is a plan view illustrating a partial configuration of a display apparatus according to an embodiment;

FIG. 16 is a plan view illustrating a partial configuration of a display apparatus according to an embodiment;

FIG. 17 is a block diagram of an electronic apparatus according to an embodiment; and

FIG. 18 shows schematic views of electronic apparatuses according to various embodiments.

### DETAILED DESCRIPTION

Reference will now be made in detail to embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to the present embodiments, and particular embodiments will be illustrated in the drawings and described in the detailed description section. The effect and features of the disclosure, and a method to achieve the same, will be clearer referring to the detailed descriptions below with the drawings. However, the present embodiments may be implemented in various forms, not by being limited to the embodiments presented below.

Hereinafter, embodiments of the disclosure will be described in detail with reference to the accompanying drawings, and in the description with reference to the drawings, the same or corresponding components are indicated by the same reference numerals and redundant descriptions thereof are omitted.

In the following embodiment, it will be understood that although the terms “first,” “second,” etc. may be used herein to describe various components, these components should not be limited by these terms. These terms are only used to distinguish one component from another.

In the following embodiment, the expression of singularity in the present specification includes the expression of plurality unless clearly specified otherwise in context.

In the following embodiment, it will be further understood that the terms “comprises” and/or “comprising” used herein specify the presence of stated features or components, but do not preclude the presence or addition of one or more other features or components.

In the following embodiment, it will be understood that when a layer, area, or component is referred to as being “formed on” another layer, area, or component, it can be directly or indirectly formed on the other layer, area, or component. That is, for example, intervening layers, areas, or components may be present.

Sizes of components in the drawings may be exaggerated or reduced for convenience of explanation. In other words, since sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

It will be understood that when a layer, area, or component is referred to as being “connected to” another layer, area, or component, it can be directly or indirectly connected to the other layer, area, or component. That is, for example, intervening layers, areas, or components may be present. For example, in the present specification, when a layer, area, or component is electrically connected to another layer, area, or component, the layers, areas, or components may not only be directly electrically connected, but may also be indirectly electrically connected via another layer, area, or component therebetween.

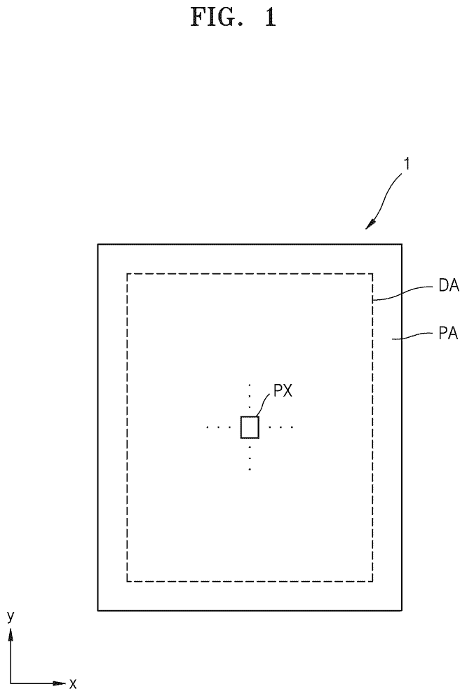

FIG. 1 is a plan view schematically illustrating a display apparatus according to an embodiment.

Referring to FIG. 1, a display apparatus 1 may include a display area DA and a peripheral area PA outside the display area DA. The display area DA displays an image and is where a plurality of pixels PX may be arranged. The display area DA may have various shapes, such as a circle, an ellipse, a polygon, or a specific shape. The plurality of pixels PX may be implemented by various light-emitting elements such as an organic light-emitting element, an inorganic light-emitting element, and a quantum dot light-emitting element, and a light-emitting element may be driven by being connected to a pixel circuit.

The peripheral area PA of the display apparatus 1 may be arranged outside the display area DA. In the peripheral area PA, a driving integrated circuit (IC) configured to provide an electrical signal to be applied to the display area DA may be arranged and various wirings configured to transmit the electrical signal generated by the driving IC may be arranged.

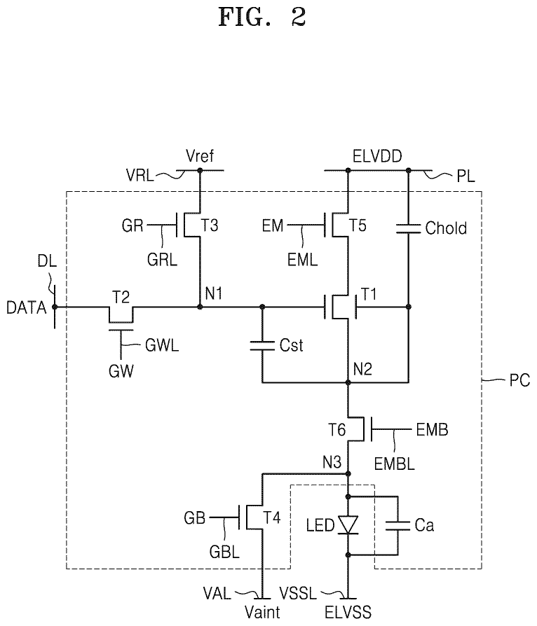

FIG. 2 is an equivalent circuit diagram schematically illustrating a light-emitting diode LED, which is a light-emitting element corresponding to any one pixel of the display apparatus 1 according to an embodiment, and a pixel circuit PC electrically connected to the light-emitting diode LED.

The pixel circuit PC may be electrically connected to a first gate line GWL configured to transmit a first gate signal GW, a second gate line GRL configured to transmit a second gate signal GR, a third gate line EML configured to transmit a third gate signal EM, a fourth gate line GBL configured to transmit a fourth gate signal GB, a fifth gate line EMBL configured to transmit a fifth gate signal EMB, and a data line DL configured to transmit a data signal DATA. Light emission of the light-emitting diode LED is controlled by the third gate signal EM and the fifth gate signal EMB, and thus, the third gate signal EM and the fifth gate signal EMB are emission control signals, and the third gate line EML and the fifth gate line EMBL may represent emission control lines. The pixel circuit PC may be electrically connected to a driving voltage line PL configured to transmit a driving voltage ELVDD, a reference voltage line VRL configured to transmit a reference voltage Vref, and a first initialization voltage line VAL configured to transmit a first initialization voltage Vaint.

The pixel circuit PC may include first to sixth transistors T1, T2, T3, T4, T5, and T6, a storage capacitor Cst, a holding capacitor Chold, and an auxiliary capacitor Ca.

The first transistor T1 may be a driving transistor configured to output a driving current corresponding to the data signal DATA, and the second to sixth transistors T2, T3, T4, T5, and T6 may be switching transistors configured to transmit signals.

In an embodiment, the first to sixth transistors T1 to T6 may each be an n-channel MOSFET (NMOS). The first to sixth transistors T1 to T6 may include an oxide semiconductor material. However, the disclosure is not limited thereto, and at least one of the first to sixth transistors T1 to T6 may be a p-channel MOSFET (PMOS). For example, the fifth transistor T5 and/or the sixth transistor T6 may be a PMOS while the other transistors may each be an NMOS, and various modifications may be made.

A first terminal (or a first electrode) and a second terminal (or a second electrode) of each of the first to sixth transistors T1, T2, T3, T4, T5, and T6 may be a source (or a source electrode) or a drain (or a drain electrode) according to voltages of the first terminal and the second terminal. For example, according to the voltages of the first terminal and the second terminal, the first terminal may be a drain and the second terminal may be a source, or the first terminal may be a source and the second terminal may be a drain. Hereinafter, a node to which a 1-1 gate electrode of the first transistor T1 is connected may be defined as a first node N1 and a node to which the second terminal of the first transistor T1 is connected may be defined as a second node N2.

The first transistor T1 may be connected to the driving voltage line PL and the light-emitting diode LED. The first transistor T1 may be connected between the fifth transistor T5 and the sixth transistor T6. The first transistor T1 may include a first gate (or a first gate electrode) connected to the first node N1, the first terminal connected to the driving voltage line PL via the fifth transistor T5, and the second terminal connected to the second node N2. The first transistor T1 may include a 1-1 gate connected to the first node N1. The first transistor T1 may further include a 1-2 gate connected to its second terminal. The 1-1 gate and the 1-2 gate may be arranged to face each other in different layers. For example, the 1-1 gate and the 1-2 gate of the first transistor T1 may face each other with a semiconductor layer therebetween. Throughout the present specification, the first gate (or the first gate electrode) of the first transistor T1 may refer to the 1-1 gate (or the 1-1 gate electrode) that is involved in turning on or turning off the first transistor T1.

A gate (or the 1-1 gate) of the first transistor T1 may be connected to the second terminal of the second transistor T2, the first terminal of the third transistor T3, and the storage capacitor Cst. The 1-2 gate of the first transistor T1 may be connected to the first terminal of the sixth transistor T6, the storage capacitor Cst, and the holding capacitor Chold. The first terminal of the first transistor T1 may be connected to the driving voltage line PL via the fifth transistor T5, and the second terminal of the first transistor T1 may be connected to a pixel electrode of the light-emitting diode LED via the sixth transistor T6. The first terminal of the first transistor T1 may be connected to the second terminal of the fifth transistor T5. The second terminal of the first transistor T1 may be connected to the first terminal of the sixth transistor T6, the storage capacitor Cst, and the holding capacitor Chold. The first transistor T1 may be configured to receive the data signal DATA according to a switching operation of the second transistor T2 and control the amount of driving current flowing to the light-emitting diode LED.

The second transistor T2 may be connected between the data line DL and the 1-1 gate of the first transistor T1. The second transistor T2 may include a gate connected to the first gate line GWL, the first terminal connected to the data line DL, and the second terminal connected to the first node N1. The second terminal of the second transistor T2 may be connected to the 1-1 gate of the first transistor T1, the first terminal of the third transistor T3, and the storage capacitor Cst. The second transistor T2 may be turned on in response to the first gate signal GW transmitted via the first gate line GWL to electrically connect the data line DL to the first node N1 and transmit the data signal DATA transmitted via the data line DL to the first node N1.

The third transistor T3 may be connected between the 1-1 gate of the first transistor T1 and the reference voltage line VRL. The third transistor T3 may include a gate connected to the second gate line GRL, the first terminal connected to the first node N1, and the second terminal connected to the reference voltage line VRL. The first terminal of the third transistor T3 may be connected to the 1-1 gate of the first transistor T1, the second terminal of the second transistor T2, and the storage capacitor Cst. The third transistor T3 may be turned on in response to the second gate signal GR transmitted via the second gate line GRL to transmit the reference voltage Vref transmitted via the reference voltage line VRL to the first node N1.

The fourth transistor T4 may be connected to the sixth transistor T6 and the first initialization voltage line VAL. The fourth transistor T4 may be connected between the light-emitting diode LED and the first initialization voltage line VAL. The fourth transistor T4 may include a gate connected to the fourth gate line GBL, the first terminal connected to a third node N3, and the second terminal connected to the first initialization voltage line VAL. The first terminal of the fourth transistor T4 may be connected to the second terminal of the sixth transistor T6 and the pixel electrode of the light-emitting diode LED. The fourth transistor T4 may be turned on by the fourth gate signal GB transmitted via the fourth gate line GBL to transmit the first initialization voltage Vaint transmitted via the first initialization voltage line VAL to the third node N3 and initialize the pixel electrode (for example, an anode) of the light-emitting diode LED.

The fifth transistor T5 may be connected between the driving voltage line PL and the first transistor T1. The fifth transistor T5 may include a gate connected to the third gate line EML, the first terminal connected to the driving voltage line PL, and the second terminal connected to the first terminal of the first transistor T1. The fifth transistor T5 may be turned on or turned off according to the third gate signal EM transmitted via the third gate line EML.

The sixth transistor T6 may be connected between the first transistor T1 and the light-emitting diode LED. The sixth transistor T6 may be connected between the second node N2 and the third node N3. The sixth transistor T6 may include a gate connected to the fifth gate line EMBL, the first terminal connected to the second node N2, and the second terminal connected to the third node N3. The first terminal of the sixth transistor T6 may be connected to the second terminal of the first transistor T1, the storage capacitor Cst, and the holding capacitor Chold. The second terminal of the sixth transistor T6 may be connected to the first terminal of the fourth transistor T4 and the pixel electrode of the light-emitting diode LED. The sixth transistor T6 may be turned on or turned off according to the fifth gate signal EMB transmitted via the fifth gate line EMBL.

The storage capacitor Cst may be connected between the 1-1 gate of the first transistor T1 and the second terminal of the first transistor T1. A first electrode of the storage capacitor Cst may be connected to the first node N1 and a second electrode of the storage capacitor Cst may be connected to the second node N2. The first electrode of the storage capacitor Cst may be connected to the 1-1 gate of the first transistor T1, the second terminal of the second transistor T2, and the first terminal of the third transistor T3. The second electrode of the storage capacitor Cst may be connected to the second terminal and the 1-2 gate of the first transistor T1, a second electrode of the holding capacitor Chold, and the first terminal of the sixth transistor T6. The storage capacitor Cst may store a data voltage from which a threshold voltage of the first transistor T1 is compensated.

When the third transistor T3 and the fifth transistor T5 are turned on, the first transistor T1 may be turned on. When a voltage of the second terminal of the first transistor T1 drops to a difference (Vref−Vth1) between the reference voltage Vref and a threshold voltage Vth1 of the first transistor T1, the first transistor T1 may be turned off, and the storage capacitor Cst may store a voltage corresponding to the threshold voltage Vth1 of the first transistor T1 to compensate for the threshold voltage Vth1 of the first transistor T1.

The holding capacitor Chold may be connected between the driving voltage line PL and the second node N2. A first electrode of the holding capacitor Chold may be connected to the driving voltage line PL. The second electrode of the holding capacitor Chold may be connected to the second terminal and the 1-2 gate of the first transistor T1, the second electrode of the storage capacitor Cst, and the first terminal of the sixth transistor T6. The holding capacitor Chold may store a compensation voltage for compensating for the threshold voltage of the first transistor T1.

The capacitance of each of the storage capacitor Cst and the holding capacitor Chold may vary depending on a color of light emitted from the light-emitting diode LED.

The auxiliary capacitor Ca may be electrically connected to the sixth transistor T6, a sustain voltage line VSSL, and the pixel electrode of the light-emitting diode LED. The auxiliary capacitor Ca may store and maintain a voltage corresponding to a voltage difference between the pixel electrode of the light-emitting diode LED and the sustain voltage line VSSL, thereby preventing an increase in black luminance when the sixth transistor T6 is turned off.

The light-emitting diode LED may be connected to the first transistor T1 via the sixth transistor T6. The light-emitting diode LED includes the pixel electrode (the anode) connected to the third node N3 and an opposite electrode (a cathode) facing the pixel electrode, wherein the opposite electrode may receive a common voltage ELVSS. In an embodiment, the opposite electrode (the cathode) may extend into a display area and be electrically connected to the sustain voltage line VSSL configured to provide the common voltage ELVSS. A driving current output by the first transistor T1 may flow through the light-emitting diode LED when the fifth transistor T5 and the sixth transistor T6 are turned-on, and the light-emitting diode LED may emit light with a luminance corresponding to the magnitude of the driving current.

As described above, the first to sixth transistors T1 to T6 may include an oxide semiconductor material. Since oxide semiconductors have a high carrier mobility and a low leakage current, a voltage drop is not large even though a driving time is long. In other words, in the case of oxide semiconductors, there is no significant color change in an image due to the voltage drop even during low-frequency driving, and thus, low-frequency driving is possible. Therefore, the first to sixth transistors T1 to T6 include an oxide semiconductor material to prevent occurrence of leakage current and simultaneously implement a display apparatus with reduced power consumption.

FIG. 2 illustrates that the pixel circuit PC includes six transistors, but the disclosure is not limited thereto. In another embodiment, the number of transistors in the pixel circuit PC may be five or less or may be seven or more.

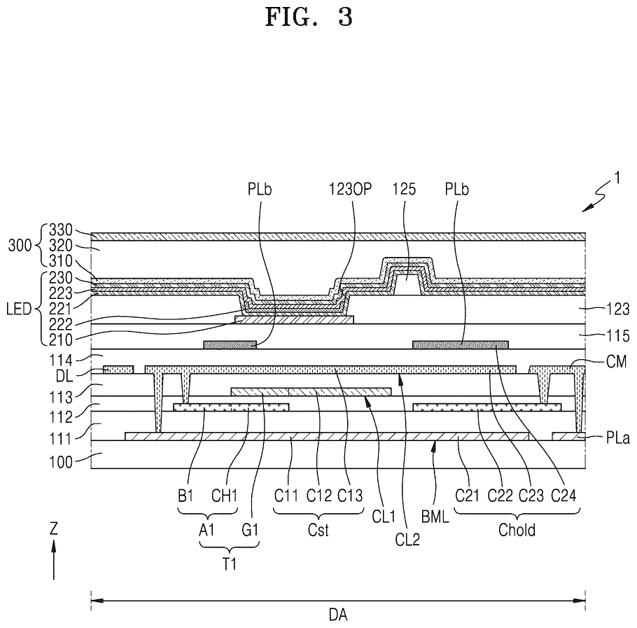

FIG. 3 is a cross-sectional view schematically illustrating a portion of the display apparatus 1 according to an embodiment.

Referring to FIG. 3, the display apparatus 1 includes the light-emitting diode LED arranged in the display area DA. The light-emitting diode LED may be arranged on a substrate 100, and a pixel circuit may be arranged between the substrate 100 and the light-emitting diode LED. In an embodiment, FIG. 3 illustrates the first transistor T1, the storage capacitor Cst, and the holding capacitor Chold as some components of the pixel circuit.

The first transistor T1 may include a first semiconductor layer A1 and a first gate electrode G1 overlapping the first semiconductor layer A1. The first transistor T1 may be a driving transistor.

The storage capacitor Cst may include a first storage electrode C11, a second storage electrode C12, and a third storage electrode C13, which are arranged in different layers and overlap each other.

The first storage electrode C11 and the third storage electrode C13 may be connected to each other via a contact hole. The second storage electrode C12 may be connected to the first gate electrode G1. The second storage electrode C12 may be integrally provided with the first gate electrode G1. The third storage electrode C13 may be connected to the first semiconductor layer A1 via a contact hole.

The holding capacitor Chold may include a first holding electrode C21, a second holding electrode C22, a third holding electrode C23, and a fourth holding electrode C24 which are arranged in different layers and overlap each other.

The first holding electrode C21 and the third holding electrode C23 may be connected to each other via a contact hole. The second holding electrode C22 and the fourth holding electrode C24 may receive a same constant voltage. The first holding electrode C21 may be connected to the first storage electrode C11. The first holding electrode C21 may be integrally provided with the first storage electrode C11. The second holding electrode C22 may be arranged in the same layer as the first semiconductor layer A1. The third holding electrode C23 may be integrally provided with the third storage electrode C13. The fourth holding electrode C24 may be integrally provided with an upper driving voltage line PLb.

The substrate 100 may include a glass material or polymer resin. In an embodiment, the substrate 100 may have a structure in which a base layer including polymer resin and a barrier layer including an inorganic insulating material such as silicon oxide or silicon nitride are alternately stacked. Polymer resin may include polyethersulfone, polyarylate, polyether imide, polyethylene naphthalate, polyethylene terephthalate, polyphenylene sulfide, polyimide, polycarbonate, cellulose triacetate, cellulose acetate propionate, etc.

A lower metal layer BML and a lower driving voltage line PLa may be arranged on the substrate 100. The lower metal layer BML may function as the first storage electrode C11 of the storage capacitor Cst and the first holding electrode C21 of the holding capacitor Chold. In other words, the lower metal layer BML may include the first storage electrode C11 and the first holding electrode C21. The first storage electrode C11 and the first holding electrode C21 may be arranged on the substrate 100.

The lower driving voltage line PLa may be a wiring configured to transmit the driving voltage ELVDD (see FIG. 2).

The lower metal layer BML and the lower driving voltage line PLa may include at least one material selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). In some embodiments, the lower metal layer BML may be a single layer of molybdenum, or may have a bilayer structure in which a molybdenum layer and a titanium layer are stacked or a trilayer structure in which a titanium layer, an aluminum layer, and a titanium layer are stacked.

A first insulating layer 111 may be arranged on the substrate 100 to cover the lower metal layer BML and the lower driving voltage line PLa. In other words, the first insulating layer 111 may cover the first storage electrode C11 of the storage capacitor Cst and the first holding electrode C21 of the holding capacitor Chold. The first insulating layer 111 may include an inorganic insulating material such as silicon oxide, silicon nitride, or silicon oxynitride, and may have a single-layered or multilayer structure including the inorganic insulating material. A semiconductor layer may be arranged on the first insulating layer 111.

In this regard, FIG. 3 illustrates that the first semiconductor layer A1 of the first transistor T1 and the second holding electrode C22 of the holding capacitor Chold are arranged on the first insulating layer 111. The first semiconductor layer A1 may include a channel area CH1 and conductive areas arranged at opposite sides of the channel area CH1, and in this regard, FIG. 3 illustrates a first area B1, which is one of the conductive areas arranged on one side of the channel area CH1. The second holding electrode C22 of the holding capacitor Chold may include the same material as the first semiconductor layer A1 and may be electrically conductive. The second holding electrode C22 may overlap the first holding electrode C21 with the first insulating layer 111 therebetween.

The first semiconductor layer A1 and the second holding electrode C22 of the holding capacitor Chold may include at least one oxide semiconductor material selected from a group consisting of indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). For example, the first semiconductor layer A1 may be an InSnZnO (ITZO) semiconductor layer, an InGaZnO (IGZO) semiconductor layer, etc. A conductivity enhancement process by plasma treatment, etc. may be performed on a partial area of the first semiconductor layer A1 and the second holding electrode C22.

A second insulating layer 112 may be arranged on the first insulating layer 111 to cover the first semiconductor layer A1 and the second holding electrode C22 of the holding capacitor Chold. The second insulating layer 112 may be arranged on the first semiconductor layer A1 and the second holding electrode C22 of the holding capacitor Chold. The second insulating layer 112 may include an inorganic insulating material such as silicon oxide, silicon nitride, or silicon oxynitride, and may have a single-layered or multilayer structure including the inorganic insulating material.

A first conductive layer CL1 may be arranged on the second insulating layer 112. The first conductive layer CL1 may function as the first gate electrode G1 and the second storage electrode C12 of the storage capacitor Cst. In other words, the first conductive layer CL1 may include the first gate electrode G1 and the second storage electrode C12 of the storage capacitor Cst. The first gate electrode G1 may overlap the channel area CH1 of the first semiconductor layer A1 with the second insulating layer 112 disposed therebetween. The second storage electrode C12 may overlap the first storage electrode C11 with the first insulating layer 111 and the second insulating layer 112 disposed therebetween.

The first conductive layer CL1 may include at least one material selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). In some embodiments, the first conductive layer CL1 may be a single layer of molybdenum, or may have a bilayer structure in which a molybdenum layer and a titanium layer are stacked or a trilayer structure in which a titanium layer, an aluminum layer, and a titanium layer are stacked.

A third insulating layer 113 may be arranged on the second insulating layer 112 to cover the first conductive layer CL1. The third insulating layer 113 may be arranged on the first gate electrode G1 and the second storage electrode C12 of the storage capacitor Cst. The third insulating layer 113 may include an inorganic insulating material such as silicon oxide, silicon nitride, or silicon oxynitride, and may have a single-layered or multilayer structure including the inorganic insulating material.

A second conductive layer CL2, the data line DL, and a connection electrode CM may be arranged on the third insulating layer 113. The second conductive layer CL2 may function as the third storage electrode C13 of the storage capacitor Cst and the third holding electrode C23 of the holding capacitor Chold. The second conductive layer CL2 may be connected to the lower metal layer BML and the first area B1 of the first semiconductor layer A1 via contact holes, respectively. In other words, the third storage electrode C13 may be connected to the first storage electrode C11 via a contact hole. The third storage electrode C13 may overlap the second storage electrode C12 with the third insulating layer 113 disposed therebetween. The third holding electrode C23 may overlap the second holding electrode C22 with the second insulating layer 112 and the third insulating layer 113 disposed therebetween.

The data line DL may be arranged in the same layer as the second conductive layer CL2. The data line DL may be arranged in the same layer as the third storage electrode C13 and the third holding electrode C23. The connection electrode CM may connect the second holding electrode C22 and the lower driving voltage line PLa to each other via contact holes. In other words, the second holding electrode C22 may be connected to the lower driving voltage line PLa via the connection electrode CM and may receive a driving voltage which is a constant voltage.

The second conductive layer CL2, the data line DL, and the connection electrode CM may include at least one material selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). In some embodiments, each of the second conductive layer CL2, the data line DL, and the connection electrode CM may be a single layer of molybdenum, or may have a bilayer structure in which a molybdenum layer and a titanium layer are stacked or a trilayer structure in which a titanium layer, an aluminum layer, and a titanium layer are stacked.

A fourth insulating layer 114 may be arranged on the third insulating layer 113 to cover the second conductive layer CL2, the data line DL, and the connection electrode CM. The fourth insulating layer 114 may include an organic insulating material. For example, the fourth insulating layer 114 may include photoresist, benzocyclobutene (BCB), polyimide, hexamethyldisiloxane (HMDSO), polymethylmethacrylate (PMMA), polystyrene, a polymer derivative with a phenolic group, an acrylic polymer, an imide polymer, an aryl ether-based polymer, an amide-based polymer, a fluorine-based polymer, a p-xylene-based polymer, a vinyl alcohol-based polymer, or a mixture thereof.

The upper driving voltage line PLb may be arranged on the fourth insulating layer 114. Part of the upper driving voltage line PLb may function as the fourth holding electrode C24 of the holding capacitor Chold. Alternatively, the fourth holding electrode C24 may be provided as part of the upper driving voltage line PLb. The fourth holding electrode C24 may be arranged on the fourth insulating layer 114 and may overlap the third holding electrode C23 with the fourth insulating layer 114 disposed therebetween.

The upper driving voltage line PLb and the fourth holding electrode C24 may include at least one material selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). In some embodiments, each of the upper driving voltage line PLb and the fourth holding electrode C24 may be a single layer of molybdenum, or may have a bilayer structure in which a molybdenum layer and a titanium layer are stacked or a trilayer structure in which a titanium layer, an aluminum layer, and a titanium layer are stacked.

A fifth insulating layer 115 may be arranged on the fourth insulating layer 114 to cover the upper driving voltage line PLb and the fourth holding electrode C24. The fifth insulating layer 115 may include an organic insulating material. For example, the fifth insulating layer 115 may include photoresist, BCB, polyimide, HMDSO, PMMA, polystyrene, a polymer derivative with a phenolic group, an acrylic polymer, an imide polymer, an aryl ether-based polymer, an amide-based polymer, a fluorine-based polymer, a p-xylene-based polymer, a vinyl alcohol-based polymer, or a mixture thereof.

The light-emitting diode LED may be arranged on the fifth insulating layer 115. The light-emitting diode LED may include a pixel electrode 210, an emission layer 222, and an opposite electrode 230.

The pixel electrode 210 may be arranged on the fifth insulating layer 115. The pixel electrode 210 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In another embodiment, the pixel electrode 210 may further include a conductive oxide layer above and/or below the reflective film. The conductive oxide layer may include indium tin oxide (ITO), indium zinc oxide (IZO), zinc oxide (ZnO), indium oxide (In₂O₃), indium gallium oxide (IGO), and/or aluminum zinc oxide (AZO). In an embodiment, the pixel electrode 210 may have a three-layer structure of ITO layer/Ag layer/ITO layer.

A bank layer 123 may be arranged on the pixel electrode 210. The bank layer 123 may include an opening 123OP disposed in an area corresponding to the pixel electrode 210 and may cover an edge of the pixel electrode 210. The bank layer 123 may include an organic insulating material. In some embodiments, the bank layer 123 may include a light-transmissive organic insulating material. In another embodiment, the bank layer 123 may include an organic insulating material including a light-blocking material. In some embodiments, the bank layer 123 may include a polyimide (PI)-based binder, and a pigment in which red, green, and blue colors are mixed. Alternatively, the bank layer 123 may include a cardo-based binder resin and a mixture of a lactam black pigment and a blue pigment. Alternatively, the bank layer 123 may include carbon black. The bank layer 123 may improve a contrast of the display apparatus 1.

A spacer 125 may be arranged on the bank layer 123. The spacer 125 may include a different material from the bank layer 123. For example, the bank layer 123 includes a negative photosensitive material while the spacer 125 includes a positive photosensitive material, and the bank layer 123 and the spacer 125 may each be formed via a separate mask process. In another embodiment, the spacer 125 may include the same material as the bank layer 123 and may be formed together with the bank layer 123 in the same mask process (for example, a halftone mask process).

The emission layer 222 may include a polymer or low-molecular-weight organic material that emits light of a certain color. The emission layer 222 may include a material that emits red light, green light, or blue light according to the light-emitting diode LED.

A functional layer may be further included under and/or over the emission layer 222. For example, a first functional layer 221 may be further included between the pixel electrode 210 and the emission layer 222, and a second functional layer 223 may be further included between the emission layer 222 and the opposite electrode 230 described below. The first functional layer 221 may include a hole transport layer and/or a hole injection layer. The second functional layer 223 may include an electron transport layer and/or an electron injection layer.

The opposite electrode 230 may include a conductive material having a low work function. For example, the opposite electrode 230 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the opposite electrode 230 may further include a layer including ITO, IZO, ZnO, or In₂O₃ on the (semi-)transparent layer including the above-described material.

Unlike the pixel electrode 210 that is individually formed to correspond to the light-emitting diode LED, the opposite electrode 230 may extend to correspond to pixel electrodes 210. For example, the pixel electrode 210 of any one light-emitting diode LED may be separated or spaced apart from the pixel electrode 210 of another light-emitting diode LED, but the opposite electrode 230 overlapping the plurality of pixel electrodes 210 may extend to cover the pixel electrodes 210.

An encapsulation layer 300 may be arranged on the light-emitting diode LED and may include at least one inorganic encapsulation layer and at least one organic encapsulation layer. In an embodiment, FIG. 3 illustrates that the encapsulation layer 300 includes a first inorganic encapsulation layer 310, an organic encapsulation layer 320, and a second inorganic encapsulation layer 330.

The first inorganic encapsulation layer 310 and the second inorganic encapsulation layer 330 may include one or more inorganic insulating materials among aluminum oxide, titanium oxide, tantalum oxide, hafnium oxide, zinc oxide, silicon oxide, silicon nitride, and silicon oxynitride. The first inorganic encapsulation layer 310 and the second inorganic encapsulation layer 330 may each be a single layer or a multilayer, each including the above-described material. The organic encapsulation layer 320 may include a polymer-based material. The polymer-based material may include acrylic resin, epoxy-based resin, polyimide, and polyethylene. In an embodiment, the organic encapsulation layer 320 may include acrylate.

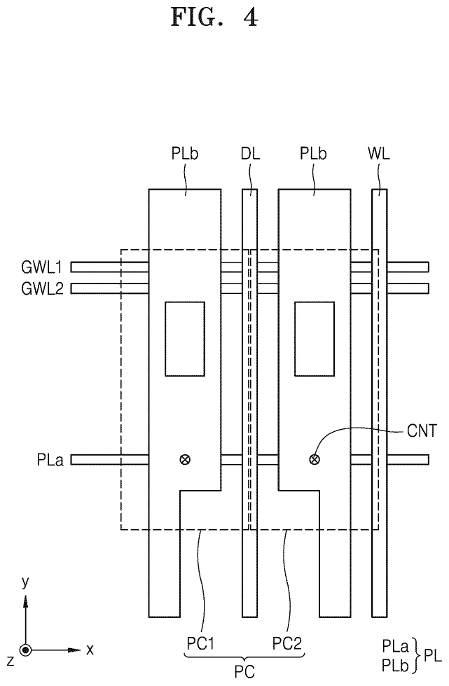

FIG. 4 is a planar layout diagram schematically illustrating a pixel circuit and some of wirings arranged in the display area DA of the display apparatus 1.

Referring to FIG. 4, the display apparatus 1 includes a 1-1 gate line GWL1 and a 1-2 gate line GWL2 extending in a first direction (an x direction), and includes the data line DL and a wiring WL extending in a second direction (a y direction) intersecting the first direction. In addition, the display apparatus 1 includes the lower driving voltage line PLa extending in the first direction and the upper driving voltage line PLb extending in the second direction.

Pixel circuits PC may be arranged in the first direction (for example, a +x-axis direction and/or a −x-axis direction) and the second direction (for example, a +y-axis direction and/or a −y-axis direction) in the display area DA. FIG. 4 illustrates a first pixel circuit PC1 and a second pixel circuit PC2 which are arranged adjacent to each other in a same row, for example, an i^{th} row.

In the present embodiment, the first pixel circuit PC1 and the second pixel circuit PC2 may share the data line DL. In other words, a second transistor of the first pixel circuit PC1 and a second transistor of the second pixel circuit PC2 may be connected to the same data line DL. The first pixel circuit PC1 and the second pixel circuit PC2 may be arranged in the first direction with the data line DL disposed therebetween. The data line DL may extend in the second direction between the first pixel circuit PC1 and the second pixel circuit PC2.

In the present embodiment, the first pixel circuit PC1 and the second pixel circuit PC2 share one data line DL which may result in a reduced number of data lines DL, and, accordingly, the number of IC chips that provide data signals may be reduced and, as a result, leading to a reduction in power consumption and costs.

In addition, by sharing the data line DL, the data line DL is arranged on one side of each of the pixel circuits PC, while other wirings WL arranged in the same layer as the data line DL may be arranged on the other side, allowing for efficient use of space. For example, the wiring WL may be used as an initialization voltage line, a sustain voltage line configured to transmit a common voltage, etc.

The first pixel circuit PC1 may be connected to a first light-emitting diode and configured to drive the first light-emitting diode and the second pixel circuit PC2 may be connected to a second light-emitting diode and configured to drive the second light-emitting diode. In an embodiment, the first light-emitting diode and the second light-emitting diode may emit light of a same color. In other words, the pixel circuits PC sharing the data line DL may be connected to the light-emitting diodes that emit light of the same color. Accordingly, there is no need to consider luminance differences based on color, and thus, power consumption may be reduced.

The pixel circuits PC sharing the data line DL may receive different gate signals from each other. The first pixel circuit PC1 may be connected to the 1-1 gate line GWL1, and the second pixel circuit PC2 may be connected to the 1-2 gate line GWL2. The pixel circuit PC arranged at a left side of the shared data line DL may be connected to the 1-1 gate line GWL1, and the pixel circuit PC arranged at a right side of the shared data line DL may be connected to the 1-2 gate line GWL2.

The driving voltage line PL may include the lower driving voltage line PLa and the upper driving voltage line PLb which are arranged in different layers from each other. The lower driving voltage line PLa may extend in the first direction and the upper driving voltage line PLb may extend in the second direction. The lower driving voltage line PLa and the upper driving voltage line PLb may be connected to each other via a contact hole CNT and form a mesh structure.

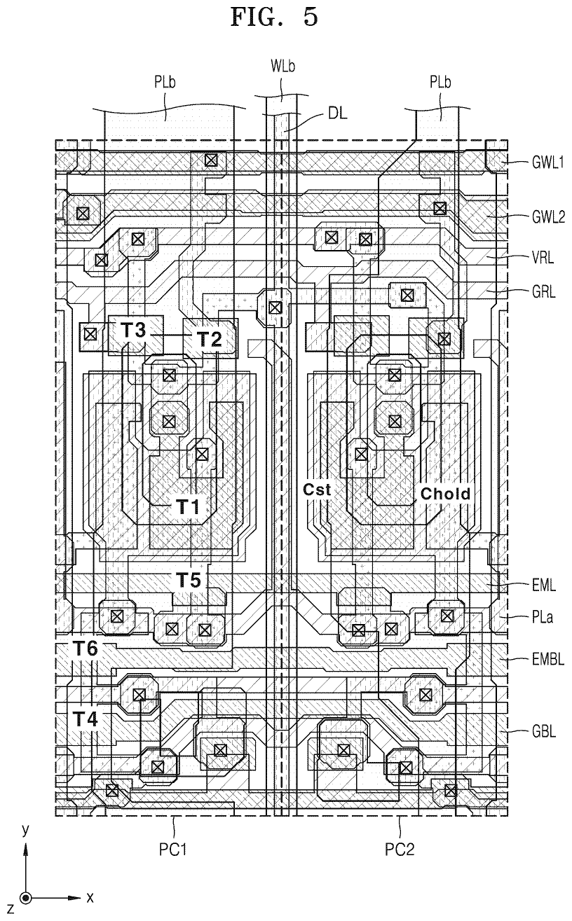

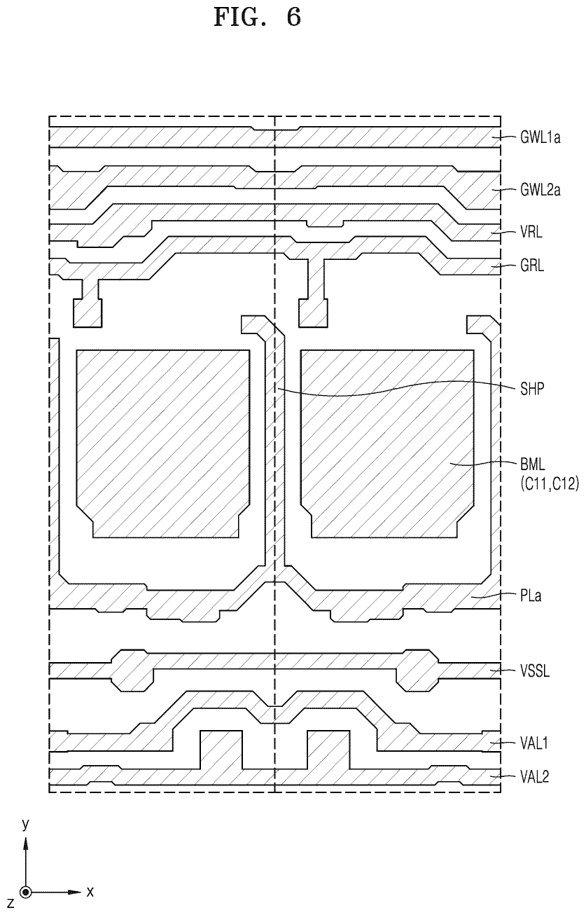

FIG. 5 is a layout diagram schematically illustrating positions of the first to sixth transistors T1 to T6, the storage capacitor Cst, and the holding capacitor Chold in pixel circuits included in a display apparatus according to an embodiment, and FIGS. 6 to 10 are layout diagrams schematically illustrating components such as the first to sixth transistors T1 to T6, the storage capacitor Cst, and the holding capacitor Chold of the display apparatus shown in FIG. 5, layer by layer.

As shown in FIGS. 5 to 10, the display apparatus includes the first pixel circuit PC1 and the second pixel circuit PC2 which are arranged in parallel in the first direction with the data line DL disposed therebetween. A structure as shown in FIGS. 5 to 10 may be repeatedly arranged in the first direction (an x-axis direction) and/or the second direction (a y-axis direction).

Each of the first pixel circuit PC1 and the second pixel circuit PC2 may include the first to sixth transistors T1 to T6, the storage capacitor Cst, and the holding capacitor Chold. Most of components included in the first pixel circuit PC1 may be arranged symmetrically with components included in the second pixel circuit PC2 with respect to the data line DL. In some embodiments, some components may not be arranged symmetrically. For example, the second transistor T2 and the third transistor T3 may not be arranged symmetrically with respect to the data line DL. In addition, the capacitances of the storage capacitor Cst and/or the holding capacitor Chold may be different from each other.

Referring to FIGS. 3 and 6, a 1-1 lower gate line GWL1a, a 1-2 lower gate line GWL2a, the reference voltage line VRL, the second gate line GRL, the lower metal layer BML, the lower driving voltage line PLa, the sustain voltage line VSSL, a first initialization voltage line VAL1, and a second initialization voltage line VAL2 may be arranged on the substrate 100 (see FIG. 3).

The 1-1 lower gate line GWL1a, the 1-2 lower gate line GWL2 a, the reference voltage line VRL, the second gate line GRL, the lower driving voltage line PLa, the sustain voltage line VSSL, the first initialization voltage line VAL1, and the second initialization voltage line VAL2 may extend in the first direction (the x direction).

The 1-1 lower gate line GWL1a may be configured to transmit the first gate signal GW (see FIG. 2) to the first pixel circuit PC1, and the 1-2 lower gate line GWL2a may be configured to transmit the first gate signal to the second pixel circuit PC2. The reference voltage line VRL may be configured to transmit the reference voltage Vref, and the second gate line GRL may be configured to transmit a second gate signal. The sustain voltage line VSSL may be configured to transmit the common voltage ELVSS.

The lower driving voltage line PLa may be configured to transmit the driving voltage ELVDD. The lower driving voltage line PLa may include a shield portion SHP protruding in the y direction between the first pixel circuit PC1 and the second pixel circuit PC2. A constant voltage is applied to the shield portion SHP and, thus, interference caused by unintended electrical signals that may be applied to the pixel circuits may be blocked.

The first initialization voltage line VAL1 may be configured to transmit a first initialization voltage Vint1 to a pixel circuit to drive a green pixel and a blue pixel. The second initialization voltage line VAL2 may be configured to transmit a second initialization voltage Vint2 to a pixel circuit to drive a red pixel. In some embodiments, the first initialization voltage Vint1 and the second initialization voltage Vint2 may have different values from each other.

The lower metal layer BML may have an isolated shape and one lower metal layer BML may be arranged for each of the pixel circuits. The lower metal layer BML may function as the first storage electrode C11 and the first holding electrode C21. In addition, the lower metal layer BML may overlap the first gate electrode G1 and the first semiconductor layer A1, thereby preventing or minimizing light from entering the first semiconductor layer A1 from the outside. The lower metal layer BML may function as a lower gate electrode of the first transistor T1.

The first insulating layer 111 (FIG. 3) may be arranged on the 1-1 lower gate line GWL1a, the 1-2 lower gate line GWL2a, the reference voltage line VRL, the lower metal layer BML, the lower driving voltage line PLa, the sustain voltage line VSSL, the first initialization voltage line VAL1, and the second initialization voltage line VAL2.

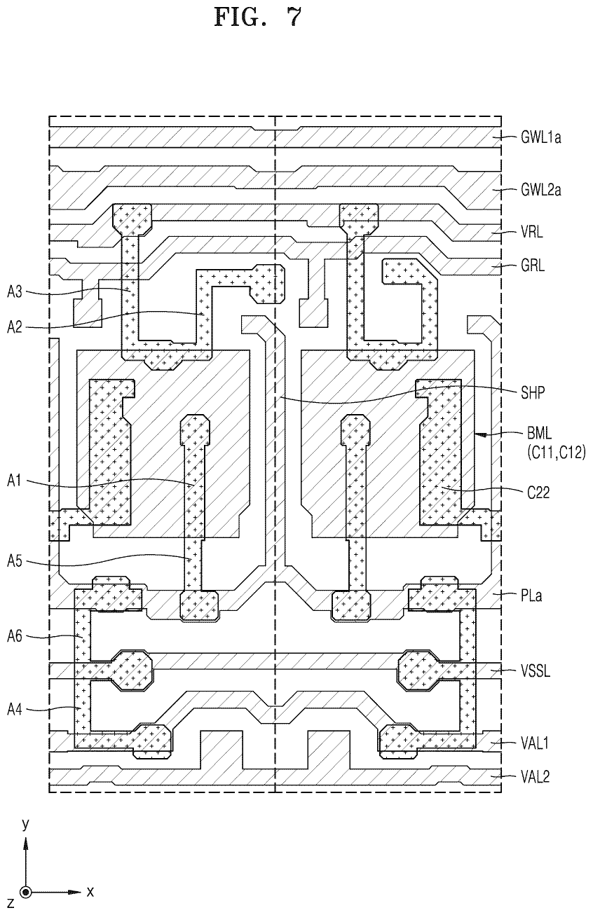

Referring to FIGS. 3 and 7, first to sixth semiconductor layers A1, A2, A3, A4, A5, and A6 and the second holding electrode C22 may be arranged on the first insulating layer 111. The first to sixth semiconductor layers A1, A2, A3, A4, A5, and A6 and the second holding electrode C22 may include the same material.

The first semiconductor layer A1 and the fifth semiconductor layer A5 may be connected to each other and formed in one piece. The second semiconductor layer A2 and the third semiconductor layer A3 may be connected to each other and formed in one piece. The fourth semiconductor layer A4 and the sixth semiconductor layer A6 may be connected to each other and formed in one piece. The first semiconductor layer A1 may be arranged adjacent to the second semiconductor layer A2 and the third semiconductor layer A3, and may be separated and spaced apart from the second semiconductor layer A2 and the third semiconductor layer A3. The fifth semiconductor layer A5 may be arranged adjacent to the sixth semiconductor layer A6 and may be separated and spaced apart from the sixth semiconductor layer A6.

The second holding electrode C22 may be arranged to overlap the lower metal layer BML. At least a portion of the lower metal layer BML, overlapping the second holding electrode C22, may be the first holding electrode C21 of the holding capacitor Chold. The second holding electrode C22 may have an isolated shape and one second holding electrode C22 may be arranged for each of the pixel circuits. A portion of the second holding electrode C22 may overlap the lower driving voltage line PLa and may be electrically connected to the lower driving voltage line PLa to receive a driving voltage.

The second insulating layer 112 (FIG. 3) may be arranged on a structure as shown in FIG. 7, for example, on the first to sixth semiconductor layers A1, A2, A3, A4, A5, and A6 and the second holding electrode C22.

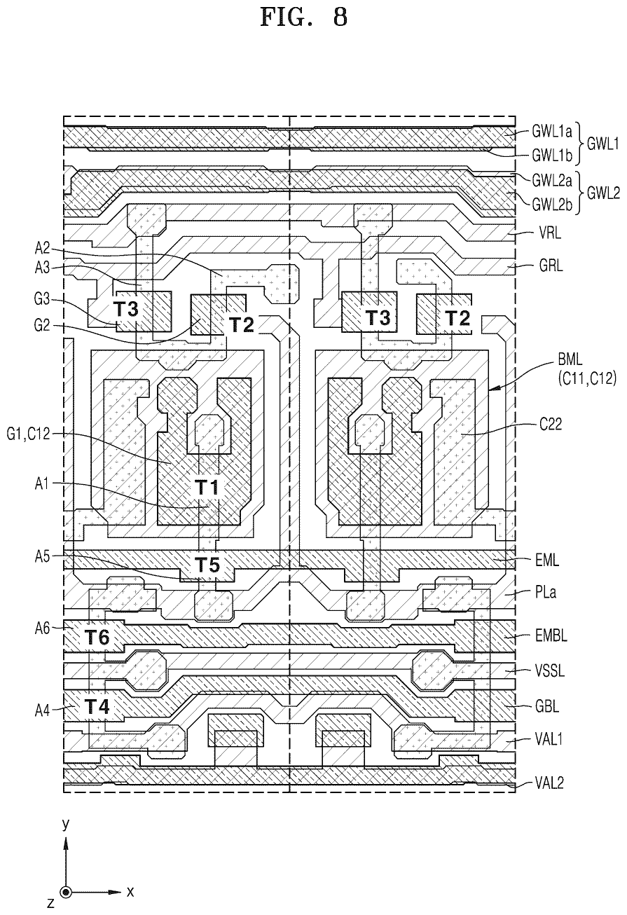

Referring to FIGS. 3 and 8, a 1-1 upper gate line GWL1b, a 1-2 upper gate line GWL2b, the third gate line EML, the fourth gate line GBL, the fifth gate line EMBL, the first gate electrode G1, a second gate electrode G2, and a third gate electrode G3 may be arranged on the second insulating layer 112.

The 1-1 upper gate line GWL1b, the 1-2 upper gate line GWL2b, the third gate line EML, the fourth gate line GBL, and the fifth gate line EMBL may extend in the first direction (the x direction).

The 1-1 upper gate line GWL1b may be configured to transmit the first gate signal GW (see FIG. 2) to the first pixel circuit PC1 and the 1-2 upper gate line GWL2b may be configured to transmit the first gate signal to the second pixel circuit PC2. The 1-1 upper gate line GWL1b may overlap the 1-1 lower gate line GWL1a. The 1-2 upper gate line GWL2b may overlap the 1-2 lower gate line GWL2a. The 1-1 gate line GWL1 may include the 1-1 upper gate line GWL1b and the 1-1 lower gate line GWL1a. The 1-2 gate line GWL2 may include the 1-2 upper gate line GWL2b and the 1-2 lower gate line GWL2a.

The third gate line EML may be configured to transmit the third gate signal EM, the fourth gate line GBL may be configured to transmit the fourth gate signal GB, and the fifth gate line EMBL may be configured to transmit the fifth gate signal EMB.

Each of the first gate electrode G1, the second gate electrode G2, and the third gate electrode G3 may have an isolated shape. The first gate electrode G1 may overlap the first semiconductor layer A1 to form the first transistor T1. The first gate electrode G1 may function as the second storage electrode C12 of the storage capacitor Cst. The first gate electrode G1 may overlap the lower metal layer BML.

The second gate electrode G2 may overlap the second semiconductor layer A2 to form the second transistor T2. The third gate electrode G3 may overlap the third semiconductor layer A3 to form the third transistor T3.

The third gate line EML may overlap the fifth semiconductor layer A5. An area of the third gate line EML which overlaps the fifth semiconductor layer A5 may function as a fifth gate electrode. The fourth gate line GBL may overlap the fourth semiconductor layer A4. An area of the fourth gate line GBL which overlaps the fourth semiconductor layer A4 may function as a fourth gate electrode. The fifth gate line EMBL may overlap the sixth semiconductor layer A6. An area of the fifth gate line EMBL which overlaps the sixth semiconductor layer A6 may function as a sixth gate electrode.

The third insulating layer 113 (FIG. 3) may be arranged on a structure shown in FIG. 8.

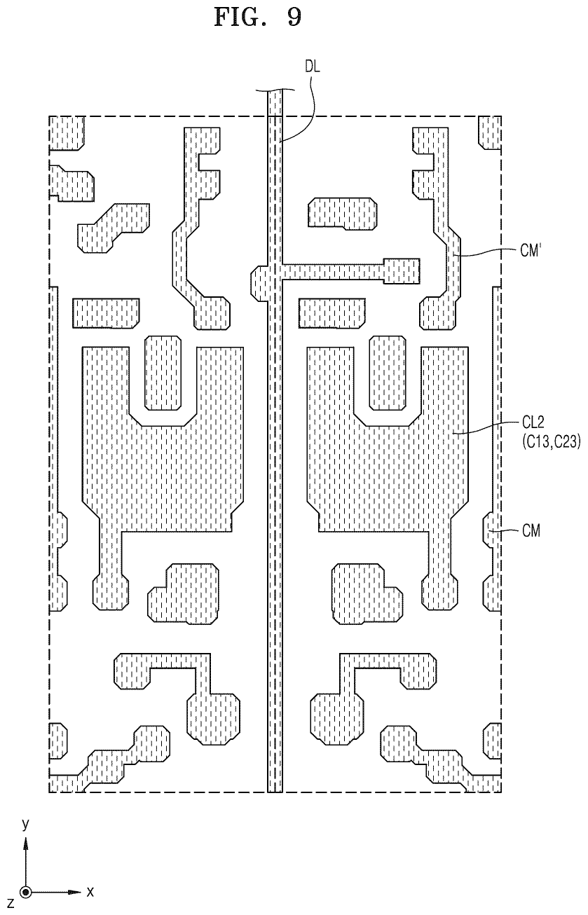

Referring to FIGS. 3 and 9, the data line DL, the second conductive layer CL2, and connection electrodes CM and CM′ may be arranged on the third insulating layer 113. The data line DL, the second conductive layer CL2, and the connection electrodes CM and CM′ may include a same material.

The data line DL may extend in the second direction (the y direction), between the first pixel circuit PC1 and the second pixel circuit PC2. The first pixel circuit PC1 and the second pixel circuit PC2 may share the data line DL.

The second conductive layer CL2 may include the third storage electrode C13 of the storage capacitor Cst and the third holding electrode C23 of the holding capacitor Chold. The connection electrodes CM and CM′ may connect components arranged thereunder to each other. Each of the second conductive layer CL2 and the connection electrodes CM and CM′ may have an isolated shape.

The fourth insulating layer 114 (FIG. 3) may be arranged on a structure shown in FIG. 9.

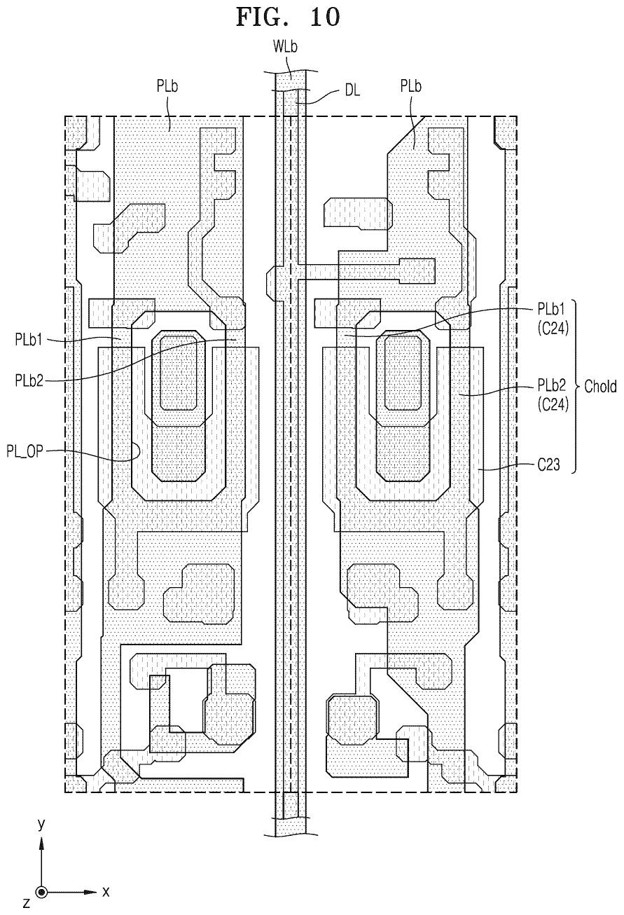

Referring to FIGS. 3 and 10, the upper driving voltage line PLb and a second wiring WLb may be arranged on the fourth insulating layer 114. The upper driving voltage line PLb and the second wiring WLb may extend in the second direction.

The second wiring WLb may overlap the data line DL. The second wiring WLb may be used as wiring configured to provide various signals or a constant voltage. For example, the second wiring WLb may be used as a reference voltage line or a sustain voltage line, each extending in the second direction. The second wiring WLb may shield the data line DL.

The upper driving voltage line PLb may be provided by branching into two branches in an area overlapping the second conductive layer CL2. The upper driving voltage line PLb may include a first branch PLb1 and a second branch PLb2. Alternatively, the upper driving voltage line PLb may include an opening PL_OP, from which a central portion is removed, in an area corresponding to the second conductive layer CL2. The first branch PLb1 and the second branch PLb2 included in the upper driving voltage line PLb may be arranged at opposite sides of the opening PL_OP. The first branch PLb1 may overlap the third gate electrode G3 of the third transistor T3. The second branch PLb2 may overlap the second gate electrode G2 of the second transistor T2.

The second conductive layer CL2 may function as the third holding electrode C23 of the holding capacitor Chold, and the upper driving voltage line PLb may function as the fourth holding electrode C24 of the holding capacitor Chold in an area overlapping the second conductive layer CL2. In other words, the first branch PLb1 and the second branch PLb2 may function as the fourth holding electrode C24 of the holding capacitor Chold.

The first pixel circuit PC1 and the second pixel circuit PC2 may be respectively connected to the 1-1 gate line GWL1 and the 1-2 gate line GWL2 and individually configured to receive the first gate signal, and, according to this mechanism, a luminance difference may occur between the first light-emitting diode driven by the first pixel circuit PC1 and the second light-emitting diode driven by the second pixel circuit PC2.

In order to minimize this luminance difference, in the present embodiments, the capacitance of the storage capacitor Cst and/or the holding capacitor Chold of the first pixel circuit PC1 may be different from the capacitance of the storage capacitor Cst and/or the holding capacitor Chold of the second pixel circuit PC2.

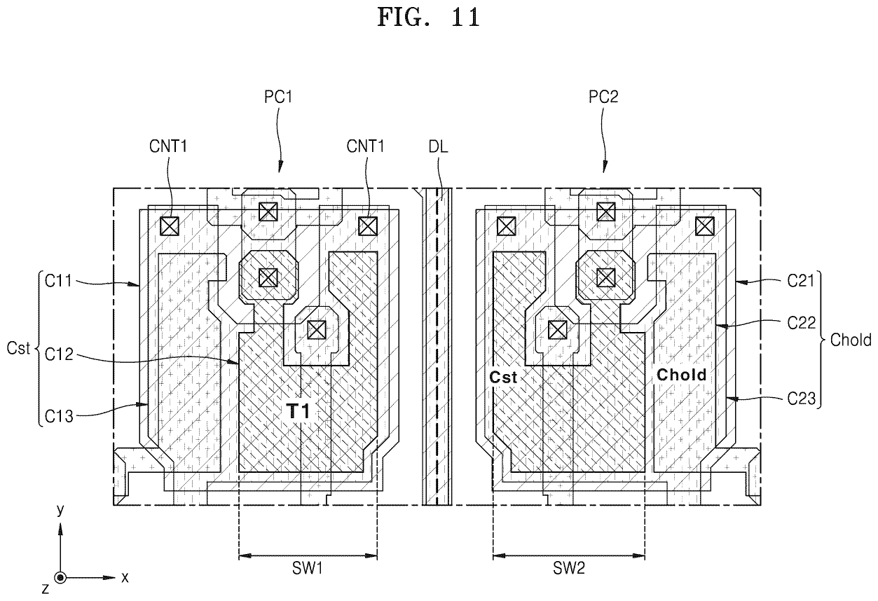

FIG. 11 is a plan view illustrating a partial configuration of a display apparatus according to an embodiment. In detail, FIG. 11 illustrates a partial configuration of the storage capacitor Cst and the holding capacitor Chold which are included in the first pixel circuit PC1 and the second pixel circuit PC2 that share the data line DL.

Referring to FIG. 11, the storage capacitor Cst may include the first storage electrode C11, the second storage electrode C12, and the third storage electrode C13 which overlap one another. The first storage electrode C11 and the third storage electrode C13 may be connected to each other via a first contact hole CNT1.

The holding capacitor Chold may include the first holding electrode C21, the second holding electrode C22, and the third holding electrode C23. The holding capacitor Chold may include the first holding electrode C21, the second holding electrode C22, the third holding electrode C23, and the fourth holding electrode C24 (FIG. 5) which overlap each other.

The first holding electrode C21 may be connected to the first storage electrode C11. The first holding electrode C21 may be integrally provided with the first storage electrode C11. The third holding electrode C23 may be connected to the third storage electrode C13. The third holding electrode C23 may be integrally provided with the third storage electrode C13. The first holding electrode C21 and the third holding electrode C23 may be connected to each other via the first contact hole CNT1.

The storage capacitor Cst may overlap the first transistor T1. The first storage electrode C11 may be connected to the first gate electrode G1 of the first transistor T1. The first storage electrode C11 may be integrally provided with the first gate electrode G1 of the first transistor T1. The first storage electrode C11 may overlap the first semiconductor layer A1 of the first transistor T1.

In the present embodiment, the capacitance of the storage capacitor Cst of the first pixel circuit PC1 may be different from the capacitance of the storage capacitor Cst of the second pixel circuit PC2.

To this end, a first width SW1 of the second storage electrode C12 of the first pixel circuit PC1 in the first direction (the x direction) may be different from a second width SW2 of the second storage electrode C12 of the second pixel circuit PC2 in the first direction (the x direction). For example, the first width SW1 may be smaller than the second width SW2. In this case, the first pixel circuit PC1 may be arranged at a left side of the data line DL, and the second pixel circuit PC2 may be arranged at a right side of the data line DL.

In contrast, the area of the first storage electrode C11 of the first pixel circuit PC1 may be equal to the area of the first storage electrode C11 of the second pixel circuit PC2, and the area of the third storage electrode C13 of the first pixel circuit PC1 may be equal to the area of the third storage electrode C13 of the second pixel circuit PC2.

The area of the second storage electrode C12 may be smaller than the area of the first storage electrode C11 and the area of the third storage electrode C13. An edge of the second storage electrode C12 may be arranged on an inner side of an edge of the first storage electrode C11 in a plan view. The edge of the second storage electrode C12 may be arranged on an inner side of an edge of the third storage electrode C13. Due to such an arrangement, the capacitance of the storage capacitor Cst may be adjusted while a process deviation is minimized by adjusting the width of the second storage electrode C12.

The first width SW1 and the second width SW2 may be set to values that minimize a difference in brightness between the first light-emitting diode connected to the first pixel circuit PC1 and the second light-emitting diode connected to the second pixel circuit PC2 while adjusting their respective brightness levels. In this case, the first light-emitting diode and the second light-emitting diode may emit light of a same color. In an embodiment, a difference between the second width SW2 and the first width SW1 may be within a range of about 0.7% to about 10% with respect to the first width SW1.

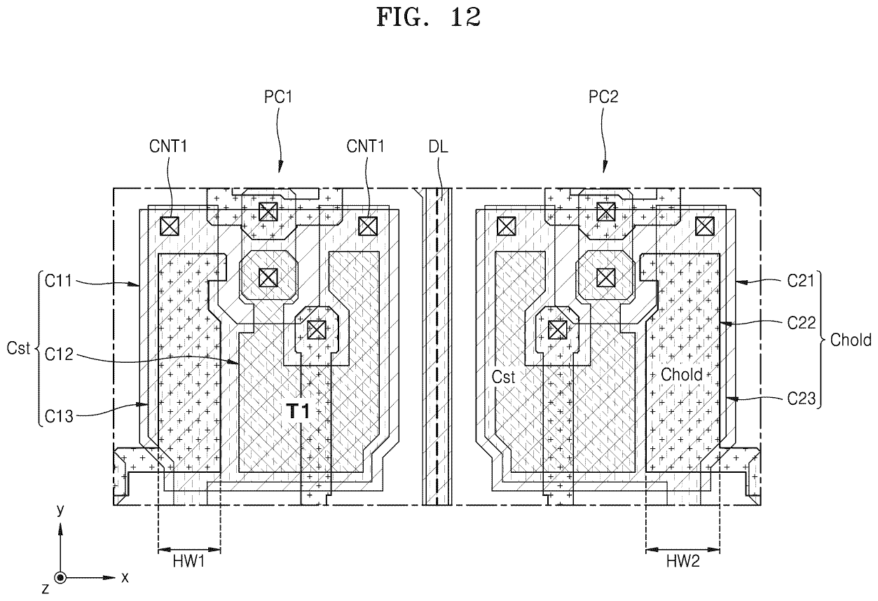

FIG. 12 is a plan view illustrating a partial configuration of a display apparatus according to an embodiment. In FIG. 12, the same reference numerals as those in FIG. 11 denote the same members.

In the present embodiment, the capacitance of the holding capacitor Chold of the first pixel circuit PC1 may be different from the capacitance of the holding capacitor Chold of the second pixel circuit PC2.

To this end, a first width HW1 of the second holding electrode C22 of the first pixel circuit PC1 in the first direction (the x direction) may be different from a second width HW2 of the second holding electrode C22 of the second pixel circuit PC2 in the first direction (the x direction). For example, the first width HW1 may be smaller than the second width HW2. In this case, the first pixel circuit PC1 may be arranged at a left side of the data line DL and the second pixel circuit PC2 may be arranged at a right side of the data line DL.

An edge of the second holding electrode C22 may be arranged on an inner side of an edge of the first holding electrode C21 in a plan view. The edge of the second holding electrode C22 may be arranged on an inner side of an edge of the third holding electrode C23. Due to such an arrangement, the capacitance of the holding capacitor Chold may be adjusted while a process deviation is minimized by adjusting the width of the second holding electrode C22.

The first width HW1 and the second width HW2 may be set to values that minimize a difference in brightness between the first light-emitting diode connected to the first pixel circuit PC1 and the second light-emitting diode connected to the second pixel circuit PC2 while adjusting their respective brightness levels. In this case, the first light-emitting diode and the second light-emitting diode may emit light of a same color.

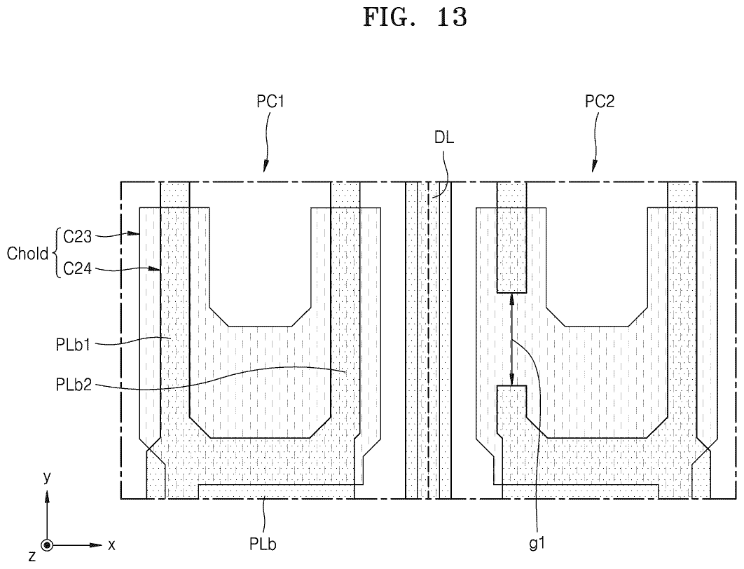

FIG. 13 is a plan view illustrating a partial configuration of a display apparatus according to an embodiment. In detail, FIG. 13 illustrates a partial configuration of the holding capacitor Chold included in each of the first pixel circuit PC1 and the second pixel circuit PC2 that share the data line DL.

The holding capacitor Chold may include the third holding electrode C23 and the fourth holding electrode C24. The fourth holding electrode C24 may be connected to the upper driving voltage line PLb. The fourth holding electrode C24 may be integrally provided with the upper driving voltage line PLb. The upper driving voltage line PLb may include the first branch PLb1 and the second branch PLb2 branched off from a main upper driving voltage line in an area overlapping the third holding electrode C23. The fourth holding electrode C24 may include the first branch PLb1 and the second branch PLb2.

In the present embodiment, the capacitance of the holding capacitor Chold of the first pixel circuit PC1 may be different from the capacitance of the holding capacitor Chold of the second pixel circuit PC2. The area of the holding capacitor Chold of the first pixel circuit PC1 may be different from the area of the holding capacitor Chold of the second pixel circuit PC2.

To this end, the first branch PLb1 and the second branch PLb2, which are included in the fourth holding electrode C24 of the first pixel circuit PC1, may be continuous in the second direction (the y direction) while any one of the first branch PLb1 and the second branch PLb2, which are included in the fourth holding electrode C24 of the first pixel circuit PC1, may be discontinuous in an area overlapping the third holding electrode C23 and thus may include a gap g1. Because the gap g1 is formed, the area of the fourth holding electrode C24 is reduced. The capacitance of the holding capacitor Chold may be adjusted by adjusting the length of the gap g1. Accordingly, the capacitance of the holding capacitor Chold of the first pixel circuit PC1 may be smaller than the capacitance of the holding capacitor Chold of the second pixel circuit PC2.

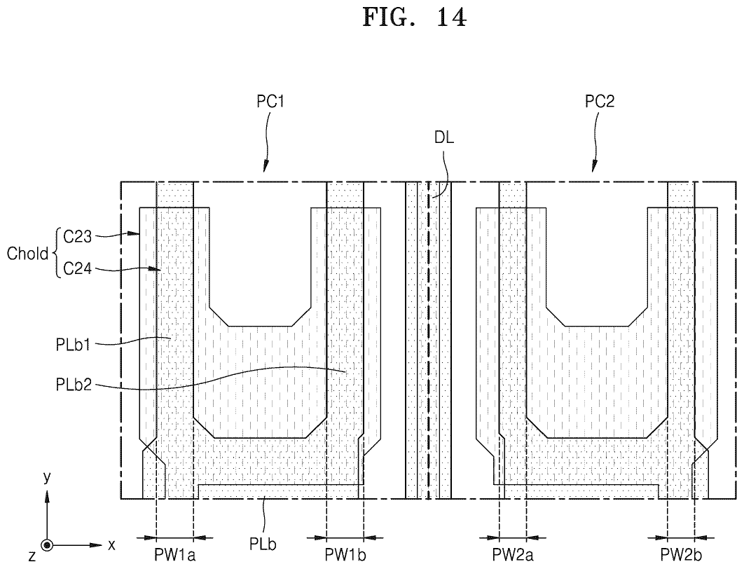

FIG. 14 is a plan view illustrating a partial configuration of a display apparatus according to an embodiment. In FIG. 14, the same reference numerals as those in FIG. 13 denote the same members.

In the present embodiment, the capacitance of the holding capacitor Chold of the first pixel circuit PC1 may be different from the capacitance of the holding capacitor Chold of the second pixel circuit PC2. The area of the holding capacitor Chold of the first pixel circuit PC1 may be different from the area of the holding capacitor Chold of the second pixel circuit PC2.

To this end, widths PW1a and PW1b of the first branch PLb1 and/or the second branch PLb2, which are included in the fourth holding electrode C24 of the first pixel circuit PC1, in the first direction (the x direction) may be different from widths PW2a and PW2b of the first branch PLb1 and/or the second branch PLb2, which are included in the fourth holding electrode C24 of the second pixel circuit PC2, in the first direction (the x direction). For example, the widths PW1a and PW1b of the first branch PLb1 and the second branch PLb2, which are included in the fourth holding electrode C24 of the first pixel circuit PC1, in the first direction (the x direction) may be greater than the widths PW2a and PW2b of the first branch PLb1 and the second branch PLb2, which are included in the fourth holding electrode C24 of the second pixel circuit PC2, in the first direction (the x direction). However, this is merely an example, and the width of any one of the first branch PLb1 and the second branch PLb2 may be adjusted.

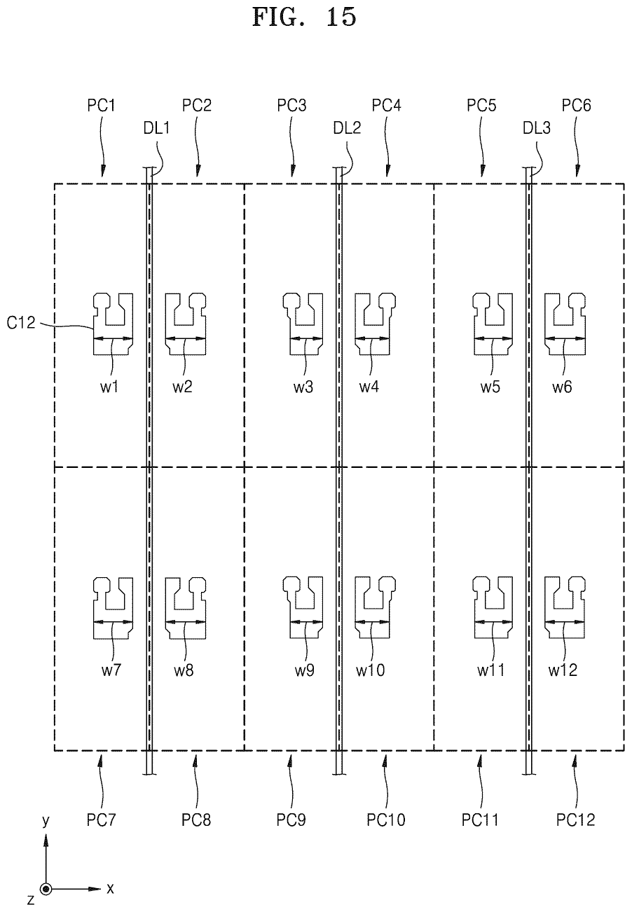

FIG. 15 is a plan view illustrating a partial configuration of a display apparatus according to an embodiment. In detail, FIG. 15 illustrates the second storage electrode C12 arranged a unit pixel which includes two pixel rows and six pixel columns. In the unit pixel, first to twelfth pixel circuits PC1 to PC 12 are disposed in the two pixel rows and the six pixel columns.

Referring to FIG. 15, in a first row, the first pixel circuit PC1 and the second pixel circuit PC2 are arranged with a first data line DL1 disposed therebetween and the third pixel circuit PC3 and the fourth pixel circuit PC4 are arranged with a second data line DL2 disposed therebetween. In addition, the fifth pixel circuit PC5 and the sixth pixel circuit PC6 are arranged with a third data line DL3 disposed therebetween.

In a second row, the seventh pixel circuit PC7 and the eighth pixel circuit PC8 are arranged with the first data line DL1 disposed therebetween and the ninth pixel circuit PC9 and the tenth pixel circuit PC10 are arranged with the second data line DL2 disposed therebetween. In addition, the eleventh pixel circuit PC11 and the twelfth pixel circuit PC12 are arranged with the third data line DL3 disposed therebetween.

The first pixel circuit PC1, the second pixel circuit PC2, the seventh pixel circuit PC7, and the eighth pixel circuit PC8 may be pixel circuits configured to drive light-emitting diodes that emit red light. The third pixel circuit PC3, the fourth pixel circuit PC4, the ninth pixel circuit PC9, and the tenth pixel circuit PC10 may be pixel circuits configured to drive light-emitting diodes that emit green light. The fifth pixel circuit PC5, the sixth pixel circuit PC6, the eleventh pixel circuit PC11, and the twelfth pixel circuit PC12 may be pixel circuits configured to drive light-emitting diodes that emit blue light.

In the present embodiment, each of the first to twelfth pixel circuits PC1 to PC12 includes the second storage electrode C12, and the width of the second storage electrode C12 arranged at a left side of each of the first, second and third data lines DL1, DL2 and DL3 may be different from the width of the second storage electrode C12 arranged at a right side thereof. (w1≠w2, w3≠w4, w5≠w6, w7≠w8, w9≠w10, w11≠w12) In some embodiments, the width of the second storage electrode C12 arranged at the left side of each of the first, second and third data lines DL1, DL2 and DL3 may be smaller than the width of the second storage electrode C12 arranged at the right side thereof. (w1<w2, w3<w4, w5<w6, w7<w8, w9<w10, w11<w12) In this case, the width refers to the width in the first direction (the x direction).

In a same column, the width of the second storage electrode C12 arranged in the first row may be different from the width of the second storage electrode C12 arranged in the second row. For example, the width w1 of the second storage electrode C12 included in the first pixel circuit PC1 may be different from the width w7 of the second storage electrode C12 included in the seventh pixel circuit PC7. In an embodiment, the widths of the second storage electrodes C12 included in the first to twelfth pixel circuits PC1 to PC12 may be different from each other. However, the disclosure is not limited thereto. In an embodiment, at least some of the widths of the second storage electrodes C12 included in the first to twelfth pixel circuits PC1 to PC12 may be the same.

The arrangement of the second storage electrodes C12 included in the two pixel rows and the six pixel columns may be repeated across the entire display apparatus.

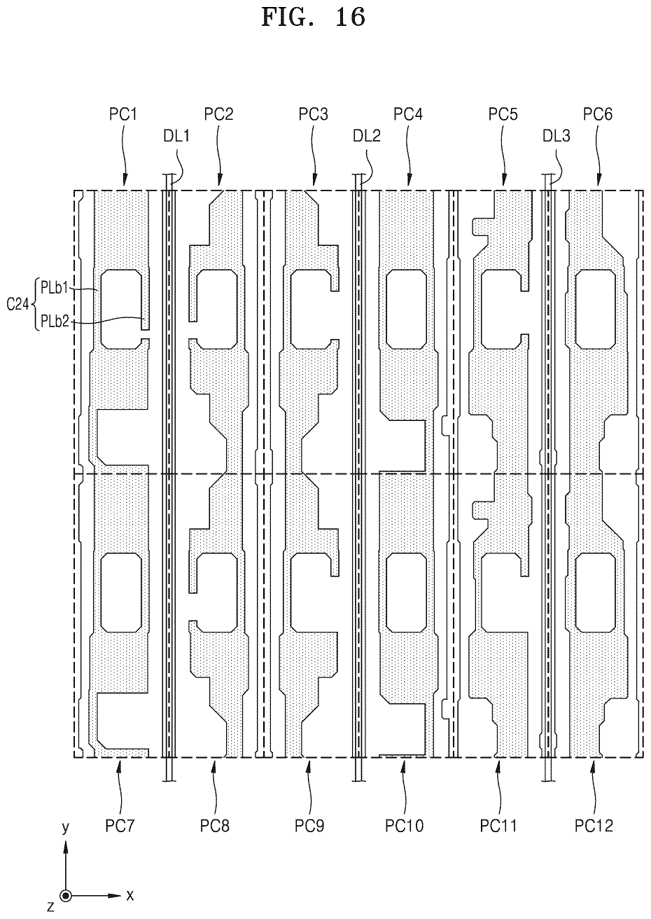

FIG. 16 is a plan view illustrating a partial configuration of a display apparatus according to an embodiment. In detail, FIG. 16 illustrates the fourth holding electrode C24 arranged in a unit pixel which includes two pixel rows and six pixel columns In the unit pixel, first to twelfth pixel circuits PC1 to PC12 in two pixel rows and six pixel columns are disposed in the two pixel rows and the six pixel columns. In FIG. 16, the same reference numerals as those in FIG. 15 denote the same members.

Referring to FIG. 16, the fourth holding electrode C24 may include the first branch PLb1 and the second branch PLb2. In the present embodiment, each of the first to twelfth pixel circuits PC1 to PC12 may include the fourth holding electrode C24. The shape of the fourth holding electrode C24 arranged at a left side of each of the first, second and third data lines DL1, DL2 and DL3 may be different from the shape of the fourth holding electrode C24 arranged at a right side thereof.

The fourth holding electrode C24 included in each of the first to twelfth pixel circuits PC1 to PC12 may have various shapes. For example, in the first pixel circuit PC1, a gap may be formed in the second branch PLb2, and, in the second pixel circuit PC2, a gap may be formed in the first branch PLb1. In the fourth pixel circuit PC4, the first branch PLb1 or the second branch PLb2 may not include a gap and may be continuous. The size of the gap formed in each of the first and second branches PLb1 and PLb2 may vary.

The arrangement of the fourth holding electrodes C24 included in a unit cell which includes two pixel rows and six pixel columns may be repeated across the entire display apparatus.

The embodiments described with reference to FIGS. 11 to 16 may be implemented in various ways, such as individually or in combination with each other. According to the above-described embodiments, a difference in luminance between light-emitting didoes may be minimized by adjusting a capacitance value of a storage capacitor and/or a holding capacitor of pixel circuits that share the data line DL.

The display apparatus according to an embodiment may be applied to various electronic apparatuses. An electronic apparatus according to an embodiment includes the above-described display apparatus, and may further include a module or apparatus having additional functions in addition to the display apparatus.

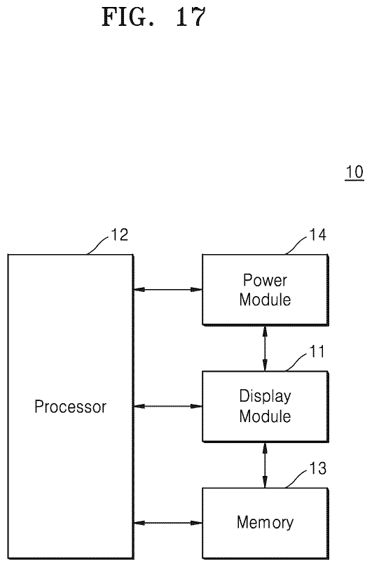

FIG. 17 is a block diagram of an electronic apparatus according to an embodiment. Referring to FIG. 17, an electronic apparatus 10 according to an embodiment may include a display module 11, a processor 12, a memory 13, and a power module 14.

The processor 12 may include at least one of a central processing unit (CPU), an application processor (AP), a graphics processing unit (GPU), a communication processor (CP), an image signal processor (ISP), and a controller.

The memory 13 may store data information required to operate the processor 12 or the display module 11. When the processor 12 executes an application stored in the memory 13, an image data signal and/or an input control signal may be transmitted to the display module 11, and the display module 11 may process the received signal and output image information via a display screen.

The power module 14 may include a power supply module such as a power adapter or a battery apparatus, and a power conversion module that converts power supplied by the power supply module and generates power required to operate the electronic apparatus 10.

At least one of the components of the electronic apparatus 10 may be included in the display apparatus according to the above-described embodiments. In addition, some individual modules functionally included within one module may be included in the display apparatus, and some others may be provided separately from the display apparatus. For example, the display apparatus includes the display module 11, and the processor 12, the memory 13, and the power module 14 may be provided in the form of other apparatuses within the electronic apparatus 10 rather than the display apparatus.

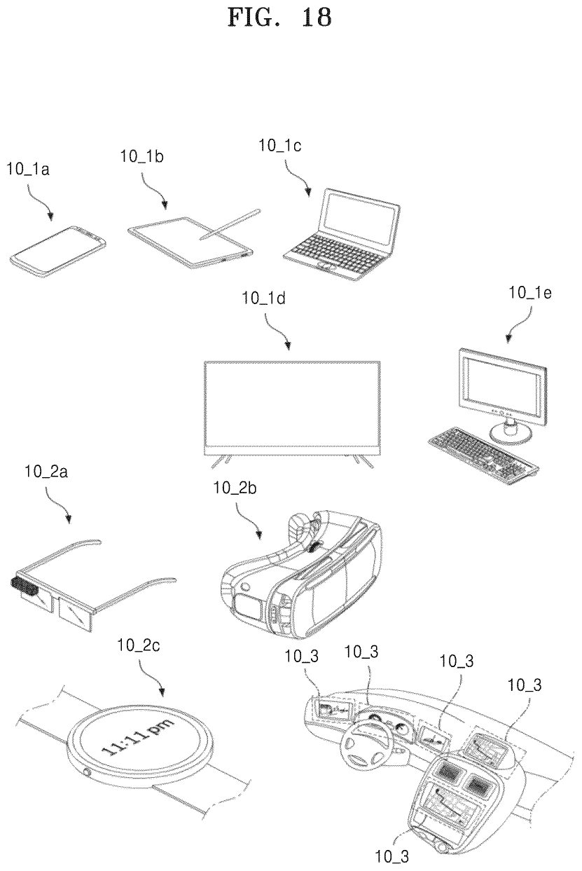

FIG. 18 shows schematic views of electronic apparatuses according to various embodiments.

Referring to FIG. 18, various electronic apparatuses, to which the display apparatus according to the embodiments is applied, may include not only image display electronic apparatuses such as a smartphone 10_1a, a tablet PC 10_1b, a laptop 10_1c, a TV 10_1d, and a desk monitor 10_1e, but also wearable electronic apparatuses including a display module such as smart glasses 10_2a, a head-mounted display 10_2b, and a smart watch 10_2c, as well as vehicle electronic apparatuses 10_3 including a display module such as an instrument panel of a vehicle, a center information display (CID) arranged on a center fascia or dashboard, and a room mirror display.

As described above, in the display apparatus and the electronic apparatus according to the disclosure, different capacitances of the storage capacitor and/or the holding capacitor are applied for each pixel circuit, and, thus, a highly reliable display apparatus and electronic apparatus may be provided.

The effect described above is merely an example, and the effect of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a 1-1 gate line and a 1-2 gate line extending in a first direction on the substrate and being spaced apart from each other;
a data line extending in a second direction intersecting the first direction; and
a first pixel circuit and a second pixel circuit arranged in the first direction with the data line therebetween,
wherein the first pixel circuit is connected to the 1-1 gate line and the second pixel circuit is connected to the 1-2 gate line, each of the first pixel circuit and the second pixel circuit comprising:
a first transistor comprising a first semiconductor layer and a first gate electrode,
a storage capacitor comprising a second storage electrode connected to the first gate electrode, and
a holding capacitor comprising a first holding electrode connected to a first storage electrode of the storage capacitor, and
wherein a capacitance of the storage capacitor of the first pixel circuit is different from a capacitance of the storage capacitor of the second pixel circuit.

2. The display apparatus of claim 1, wherein the first pixel circuit and the second pixel circuit share the data line.

3. The display apparatus of claim 1, further comprising:
a first light-emitting diode connected to the first pixel circuit; and
a second light-emitting diode connected to the second pixel circuit,
wherein the first light-emitting diode and the second light-emitting diode emit light of a same color.

4. The display apparatus of claim 1, wherein the storage capacitor further comprises a third storage electrode arranged above the second storage electrode, and
wherein the third storage electrode is connected to the first storage electrode via a contact hole.

5. The display apparatus of claim 4, wherein an area of the first storage electrode of the first pixel circuit is equal to an area of the first storage electrode of the second pixel circuit, and
wherein an area of the third storage electrode of the first pixel circuit is equal to an area of the third storage electrode of the second pixel circuit.

6. The display apparatus of claim 1, wherein a width of the second storage electrode of the first pixel circuit in the first direction is different from a width of the second storage electrode of the second pixel circuit in the first direction.

7. The display apparatus of claim 6, wherein an edge of the second storage electrode is arranged on an inner side of an edge of the first storage electrode in a plan view.

8. The display apparatus of claim 1, wherein a capacitance of the holding capacitor of the first pixel circuit is different from a capacitance of the holding capacitor of the second pixel circuit.

9. The display apparatus of claim 1, wherein the holding capacitor further comprises a second holding electrode arranged in a same layer as the first semiconductor layer, and
wherein a width of the second holding electrode of the first pixel circuit in the first direction is different from a width of the second holding electrode of the second pixel circuit in the first direction.

10. The display apparatus of claim 1, wherein the holding capacitor further comprises:
a second holding electrode arranged in a same layer as the first semiconductor layer;
a third holding electrode arranged above the first gate electrode; and
a fourth holding electrode arranged above the third holding electrode,
wherein the fourth holding electrode is provided as part of a driving voltage line extending in the second direction.

11. The display apparatus of claim 10, wherein the fourth holding electrode includes a first branch and a second branch in an area overlapping the third holding electrode,
wherein the first branch arranged in the first pixel circuit is continuous, and
wherein the first branch arranged in the second pixel circuit is discontinuous and comprises a gap.

12. The display apparatus of claim 10, wherein the fourth holding electrode includes a first branch and a second branch in an area overlapping the third holding electrode, and
wherein at least one width of the first branch and the second branch arranged in the first pixel circuit is different from a width of each of the first branch and the second branch arranged in the second pixel circuit.

13. The display apparatus of claim 1, further comprising a third pixel circuit and a fourth pixel circuit arranged in a next row with respect to the first pixel circuit and the second pixel circuit and arranged with the data line therebetween, wherein a capacitance of a storage capacitor included in the third pixel circuit is different from a capacitance of the storage capacitor included in the first pixel circuit.

14. The display apparatus of claim 13, further comprising:
a first light-emitting diode connected to the first pixel circuit;
a second light-emitting diode connected to the second pixel circuit;
a third light-emitting diode connected to the third pixel circuit; and
a fourth light-emitting diode connected to the fourth pixel circuit,
wherein the first light-emitting diode, the second light-emitting diode, the third light-emitting diode, and the fourth light-emitting diode emit light of a same color.

15. A display apparatus comprising:
a substrate;
a 1-1 gate line and a 1-2 gate line extending in a first direction on the substrate and being spaced apart from each other;
a data line extending in a second direction intersecting the first direction; and
a first pixel circuit and a second pixel circuit which share the data line and are arranged in the first direction,
wherein the first pixel circuit is connected to the 1-1 gate line and the second pixel circuit is connected to the 1-2 gate line, each of the first pixel circuit and the second pixel circuit comprising a first transistor comprising a first semiconductor layer and a first gate electrode, a storage capacitor comprising a second storage electrode connected to the first gate electrode, and a holding capacitor comprising a first holding electrode connected to a first storage electrode of the storage capacitor, and
wherein a capacitance of the holding capacitor of the first pixel circuit is different from a capacitance of the holding capacitor of the second pixel circuit.

16. The display apparatus of claim 15, wherein the holding capacitor further comprises a second holding electrode arranged in a same layer as the first semiconductor layer, and
wherein a width of the second holding electrode of the first pixel circuit in the first direction is different from a width of the second holding electrode of the second pixel circuit in the first direction.

17. The display apparatus of claim 15, wherein the holding capacitor further comprises:
a second holding electrode arranged in a same layer as the first semiconductor layer;
a third holding electrode arranged above the first gate electrode; and
a fourth holding electrode arranged above the third holding electrode, and
wherein the fourth holding electrode is provided as part of a driving voltage line extending in the second direction.

18. The display apparatus of claim 17, wherein an area of the fourth holding electrode of the first pixel circuit is different from an area of the fourth holding electrode of the second pixel circuit.

19. An electronic apparatus comprising a display apparatus, wherein the display apparatus comprises:
a substrate;
a 1-1 gate line and a 1-2 gate line extending in a first direction on the substrate and being spaced apart from each other;
a data line extending in a second direction intersecting the first direction; and
a first pixel circuit and a second pixel circuit arranged in the first direction with the data line therebetween,
wherein the first pixel circuit is connected to the 1-1 gate line and the second pixel circuit is connected to the 1-2 gate line, each of the first pixel circuit and the second pixel circuit comprising a first transistor comprising a first semiconductor layer and a first gate electrode, a storage capacitor comprising a second storage electrode connected to the first gate electrode, and a holding capacitor comprising a first holding electrode connected to a first storage electrode of the storage capacitor, and
wherein a capacitance of the storage capacitor of the first pixel circuit is different from a capacitance of the storage capacitor of the second pixel circuit, or a capacitance of the holding capacitor of the first pixel circuit is different from a capacitance of the holding capacitor of the second pixel circuit.

20. The electronic apparatus of claim 19, wherein the electronic apparatus is one of a smartphone, a tablet PC, a laptop, a TV, a desk monitor, smart glasses, a head-mounted display, a smart watch, an instrument panel of a vehicle, a center fascia, a center information display (CID), and a room mirror display.
